(19) United States
(12) Patent Application Publication
(10) Pub. No.: US 2026/0188539 A1
(43) Pub. Date: Jul. 2, 2026

(54) MgB2 SUPERCONDUCTING WIRE, METHOD FOR PRODUCING MgB2 SUPERCONDUCTING WIRE, SUPERCONDUCTING COIL, AND MAGNETIC GENERATOR

(71) Applicant: HITACHI, LTD., Tokyo (JP)

(72) Inventors: Takaaki SUZUKI, Tokyo (JP); Hideki TANAKA, Tokyo (JP); Motomune KODAMA, Tokyo (JP)

(73) Assignee: HITACHI, LTD., Tokyo (JP)

(21) Appl. No.: 18/857,777

(22) PCT Filed: Apr. 27, 2023
(86) PCT No.: PCT/JP2023/016743

§ 371 Date: Oct. 17, 2024

(30) Foreign Application Priority Data
Apr. 28, 2022 (JP) 2022-075369

(51) Int. Cl. H01B 12/10; G01R 33/3815; H01B 13/00; H01F 6/06

(52) U.S. Cl. CPC H01B 12/10; G01R 33/3815; H01B 13/0016; H01F 6/06

(57) ABSTRACT

A superconducting wire includes an element wire group having a plurality of element wires containing MgB₂ arranged in a circumferential direction and a radial direction with respect to a center of the wire, a high thermal expansion metal arranged so as to cover the element wire group and having a higher thermal expansion coefficient at room temperature than the element wires, a stabilizer that is arranged so as to cover the high thermal expansion metal and stabilizes superconduction, and a high hardness metal that is arranged so as to cover the stabilizer and has a higher hardness than that of the stabilizer. A method for manufacturing a superconducting wire includes a step of forming an embedding material having precursors of a plurality of element wires accommodated in a multi-tube, a step of wire drawing the embedding material, and a step of heat-treating the embedding material to generate MgB₂.

### TECHNICAL FIELD

The present invention relates to an MgB₂ superconducting wire using magnesium diboride (MgB₂), a method for producing an MgB₂ superconducting wire, a superconducting coil, and a magnetic generator.

### BACKGROUND ART

An advantage of a superconducting wire is that a current can flow with zero resistance. Conventionally, a wire of niobium titanium (NbTi), which is a low-temperature superconductor, has been widely used for a superconducting coil. Since the superconducting coil using an NbTi wire has a low operating temperature of about 4 K, cooling with liquid helium is performed. However, in recent years, there is a concern about the supply and demand tightness of helium. Therefore, the development of a superconductor that has a high critical temperature and does not use liquid helium and wire formation have been advanced.

As a superconductor having a high critical temperature, niobium tin (Nb₃Sn), yttrium (Y)-based oxide, bismuth (Bi)-based oxide, magnesium diboride (MgB₂), and the like are known. MgB₂ has a high critical temperature of about 39 K, and raw materials are relatively easily obtained. In addition, it has small magnetic anisotropy, is lightweight, and is excellent in mechanical properties. Therefore, an MgB₂ superconducting wire using MgB₂ as a superconductor is expected to be applied to various applications.

As a general method for producing an MgB₂ superconducting wire, a powder-in-tube (PIT) method is used in which a metal tube is filled with a powder as a raw material and the metal tube is subjected to wire drawing. The PIT method includes an ex situ method and an in situ method. The ex situ method is a method using MgB₂ synthesized in advance as a raw material. The in situ method is a method in which magnesium powder and boron powder are used as raw materials, and magnesium and boron are heat-treated to produce MgB₂.

Methods for producing a superconducting coil using an MgB₂ superconducting wire include a wind-and-react method and a react-and-wind method. The wind-and-react method is a method in which a precursor of a superconducting wire is wound in a coil shape and then subjected to heat treatment. The react-and-wind method is a method in which a heat-treated superconducting wire is wound into a coil shape.

It is known that an MgB₂ superconducting wire has an allowable bending radius, and when the wire is bent at a large curvature, superconducting properties are deteriorated. When the MgB₂ superconducting wire is bent at a large curvature below an allowable bending radius at the time of winding, routing, or the like into a coil shape, the superconducting properties such as critical current are deteriorated. Due to such properties, there is a current situation where the manufacture of a superconducting magnet using an MgB₂ superconducting wire and the like are restricted.

PTL 1 describes a wire including a filament formed of MgB₂, a base material covering the outer periphery of the filament, a high thermal expansion metal covering the outer periphery of the base material, and a stabilizer for stabilizing superconduction which covers the outer periphery of the high thermal expansion metal. The high thermal expansion metal is a metal having a higher thermal expansion coefficient at room temperature than MgB₂ and the base material.

### CITATION LIST

### Non Patent Literature

PTL 1: JP 2021-106079 A

### SUMMARY OF INVENTION

### Technical Problem

In PTL 1, a high thermal expansion metal imparts compressive residual stress to a filament of MgB₂ to increase the resistance to bending of a wire. By improving the bending strain resistance of the wire, the allowable bending radius is reduced while the critical current is ensured. However, as a result of studies by the present inventors, it has been confirmed that there is room for further improvement in the bending strain resistance of the MgB₂ superconducting wire and thinning and lengthening of the wire.

Therefore, an object of the present invention is to provide an MgB₂ superconducting wire that can achieve a reduction in bending radius to a realistic value without greatly reducing the critical current and enables further lengthening and thinning, a method for manufacturing the MgB₂ superconducting wire, a superconducting coil using the same, and a magnetic generator including the same.

### Solution to Problem

In order to solve the above problems, a superconducting wire material according to the present invention is an MgB₂ superconducting wire having a plurality of element wires containing MgB₂ and covered with a metal layer and including an element wire group having the plurality of element wires arranged in a circumferential direction and a radial direction with respect to a center of a wire, a high thermal expansion metal that is disposed so as to cover the element wire group and has a higher thermal expansion coefficient at room temperature than the element wire, a stabilizer that is disposed so as to cover the high thermal expansion metal and stabilizes superconduction, and a high hardness metal that is disposed so as to cover the stabilizer and has a higher hardness than the stabilizer.

A method for manufacturing a superconducting wire material according to the present invention is a method for manufacturing an MgB₂ superconducting wire having a plurality of element wires containing MgB₂ and covered with a metal layer, the method including a step of forming an embedding material having precursors of the plurality of element wires accommodated in a multi-tube, a step of performing a wire drawing process on the embedding material, and a step of heat-treating the embedding material subjected to the wire drawing process to produce MgB₂, in which the embedding material has the precursors of the plurality of element wires accommodated in the multi-tube and arranged in a circumferential direction and a radial direction with respect to a center of the multi-tube, and the multi-tube includes a high thermal expansion metal tube formed of a high thermal expansion metal having a higher thermal expansion coefficient at room temperature than the element wire, a stabilizer tube formed of a stabilizer for stabilizing superconduction, and a high hardness metal tube formed of a high hardness metal having a higher hardness than the stabilizer, which are arranged in this order from an inside to an outside.

### Advantageous Effects of Invention

According to the present invention, it is possible to provide an MgB₂ superconducting wire that can achieve a reduction in bending radius to a realistic value without greatly reducing the critical current and enables further lengthening and thinning, a method for manufacturing the MgB₂ superconducting wire, a superconducting coil using the same, and a magnetic generator including the same.

### BRIEF DESCRIPTION OF DRAWINGS

FIG. 1 is a sectional view schematically showing an example of an embedding material which is a precursor of an MgB₂ superconducting wire according to an embodiment of the present invention.

FIG. 2 is a sectional view schematically showing an example of an MgB₂ superconducting wire according to the embodiment of the present invention.

FIG. 3 is a sectional view schematically showing an example of an embedding material which is a material for an MgB₂ superconducting wire according to the embodiment of the present invention.

FIG. 4 is a sectional view schematically showing an example of an MgB₂ superconducting wire according to the embodiment of the present invention.

FIG. 5 is a sectional view schematically showing an example of an embedding material which is a precursor of a conventional MgB₂ superconducting wire.

FIG. 6 is a sectional view schematically illustrating an example of a superconducting coil according to the embodiment of the present invention.

FIG. 7 is a sectional view schematically illustrating an example of a magnetic generator according to the embodiment of the present invention.

### DESCRIPTION OF EMBODIMENTS

Hereinafter, an MgB₂ superconducting wire, a method for manufacturing an MgB₂ superconducting wire, a superconducting coil using the same, and a magnetic generator including the same according to an embodiment of the present invention will be described with reference to the accompanying drawings. In each drawing, common components are denoted by the same reference numerals, and a duplicate description will be omitted.

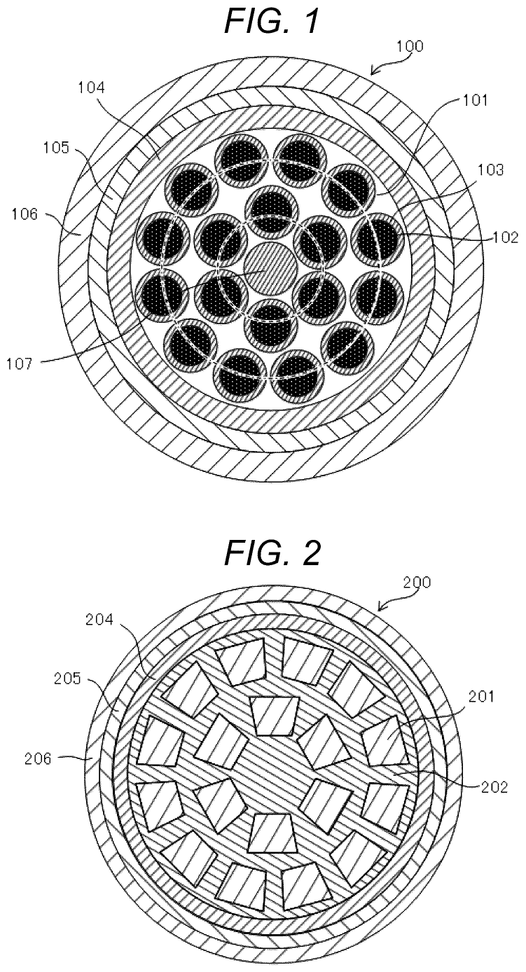

FIG. 1 is a sectional view schematically showing an example of an embedding material which is a precursor of an MgB₂ superconducting wire according to an embodiment of the present invention.

As shown in FIG. 1, the MgB₂ superconducting wire according to the present embodiment is manufactured using, as a precursor, an embedding material 100 incorporating element wire precursors 101 which are precursors of superconducting filaments. The embedding material 100 is formed by embedding the plurality of element wire precursors 101 in a regular arrangement with respect to a metal multi-tube (104, 105, 106). The element wire precursor 101 is formed by filling a metal tube 103 with a raw material powder 102.

FIG. 2 is a sectional view schematically showing an example of an MgB₂ superconducting wire according to the embodiment of the present invention.

As illustrated in FIG. 2, an MgB₂ superconducting wire 200 according to the present embodiment includes a plurality of element wires 201 which are superconducting filaments, a matrix (base material) 202 in which element wire groups are embedded, and metal layers (204, 205, and 206) having a multilayer structure.

The MgB₂ superconducting wire 200 illustrated in FIG. 2 is manufactured by performing a heat treatment after drawing the embedding material 100 illustrated in FIG. 1. The method for manufacturing the MgB₂ superconducting wire 200 according to the present embodiment includes the steps of: forming the embedding material 100 which is a precursor of the MgB₂ superconducting wire; drawing the embedding material 100; and heat-treating the embedding material 100 subjected to the drawing process to generate MgB₂.

The MgB₂ superconducting wire 200 according to the present embodiment is a superconducting wire having the plurality of element wires 201 containing MgB₂ and covered with metal layers (204, 205, and 206) having a multilayer structure. The MgB₂ superconducting wire 200 has a multi-core wire structure including the plurality of element wires 201 which are superconducting filaments. The plurality of element wires 201 are arranged in the circumferential direction and the radial direction with respect to the center of the wire to form an element wire group. In the matrix 202, the element wire group is buried inside the metal layers (204, 205, and 206).

The metal layers (204, 205, and 206) are provided in a multilayer structure in which the high thermal expansion metal 204, the stabilizer 205, and the high hardness metal 206 are arranged in this order from the inside to the outside. The high thermal expansion metal 204 is formed of the high thermal expansion metal tube 104. The stabilizer 205 is formed of the stabilizer tube 105. The high hardness metal 206 is formed of the high hardness metal tube 106.

According to the MgB₂ superconducting wire 200 according to the present embodiment, the high hardness metal 206 is provided outside the stabilizer 205, so that defects at the time of wire drawing of the embedding material 100 are prevented. The high hardness metal 206 prevents uneven deformation of the high thermal expansion metal 204 and the stabilizer 205, which occurs at the time of wire drawing. Therefore, it is possible to lengthen or thin the wire as compared with the related art. Although the multi-core wire structure in which the element wires 201 are regularly arranged is adopted, the unevenness of the element wire group is prevented.

The element wire precursor 101 is a single core wire to be embedded which is a precursor of the element wire 201, and is obtained by accommodating the raw material powder 102 containing magnesium and boron in the metal tube 103. The element wire 201 which is a superconducting filament is formed by a powder in tube (PIT) method. The PIT method is a method for preparing a wire by filling a metal tube with a raw material powder and wire-drawing the metal tube. When the embedding material 100 is subjected to a wire drawing process and then subjected to a heat treatment, the raw material powder 102 becomes the element wire 201 containing MgB₂, and the metal tube 103 becomes the matrix 202.

As a method for forming the element wire 201 containing MgB₂, either an ex situ method or an in situ method for the PIT methods may be used, but the in situ method is preferably used. According to the in situ method, MgB₂ having many bonds between particles and few voids can be generated by heat treatment at a relatively low temperature. When MgB₂ is fired at a low temperature, the density of grain boundaries serving as pinning centers increases, and thus superconducting properties such as critical current density can be improved.

A carbon source can be added to the raw material powder 102 containing magnesium and boron. When a carbon source is added, B of MgB₂ can be element-substituted by C at the time of heat treatment for producing MgB₂. Since C as an impurity is introduced into the superconductor, the critical current and the critical magnetic field of the MgB₂ superconducting wire 200 can be improved.

As the carbon source, inorganic carbon compounds such as B₄C and SiC, hydrocarbons such as benzene, naphthalene, coronene, and anthracene, organic acids such as stearic acid, magnesium salts of organic acids, and the like can be used.

The metal tube 103 accommodating the raw material powder 102 becomes the matrix 202 when the embedding material 100 is subjected to a wire drawing process and then subjected to a heat treatment, and the element wire group including the plurality of element wires 201 is embedded and mechanically supported. The metal tube 103 functions as a barrier material at the time of heat treatment for generating MgB₂. Filling the metal tube 103 as a barrier material with the raw material powder 102 will prevent the reaction between Mg or B contained in the raw material powder 102 and an inhibitor such as copper.

As a material for the metal tube 103, iron, niobium, tantalum, nickel, titanium, an alloy thereof, or the like can be used. These metals hardly react with Mg or B at the time of the heat treatment for producing MgB₂. Therefore, such a metal is effective as a barrier material without hindering the production of MgB₂. A material for the metal tube 103 is preferably iron or niobium. Since iron and niobium have good workability and are relatively inexpensive, the metal tube 103 suitable for wire drawing can be obtained at low cost.

Referring to FIG. 1, the embedding material 100 is provided in a structure in which a plurality of element wire precursors 101 are arranged in the circumferential direction and the radial direction with respect to the center of the embedding material 100. A central member 107 is disposed at the center of the embedding material 100. As the central member 107, a metal formed of a metal of a normal conductor that does not become a superconducting filament is disposed.

When the above embedding material 100 is subjected to a wire drawing process and then subjected to a heat treatment, as illustrated in FIG. 2, an element wire group in which the plurality of element wires 201 are arranged in the circumferential direction and the radial direction with respect to the center of the wire is formed. The matrix 202 made of a metal is formed at the center of the MgB₂ superconducting wire 200.

As illustrated in FIG. 1, when the central member 107 made of a metal is disposed at the center of the embedding material 100, the arrangement of the precursor group including the plurality of element wire precursors 101 can be mechanically supported by the central member 107. Therefore, it is possible to suppress the element wire precursor 101 from being biased in the radial direction of the embedding material 100 at the time of wire drawing of the embedding material 100.

As a material for the central member 107, iron, niobium, tantalum, nickel, titanium, an alloy thereof, or the like can be used. The central member 107 is preferably formed of the same metal as the metal tube 103 containing the raw material powder 102. Using the same kind of metal will reduce a processing strain difference and a thermal expansion difference between the central member 107 and the metal tube 103. At the time of wire drawing or heat treatment, a non-uniform force due to plastic deformation or thermal deformation is less likely to be applied to the element wire precursors 101, so that the element wire precursors 101 can be prevented from being biased in the radial direction of the embedding material 100.

Referring to FIG. 1, the plurality of element wire precursors 101 are arranged around the central member 107 so as to be on a first concentric circle concentric with the central member 107. The plurality of element wire precursors 101 are disposed outside the first concentric circle so as to be on a second concentric circle concentric with the central member 107. On the first concentric circle and the second concentric circle, the element wire precursors 101 are regularly arranged along the circumferential direction.

When such an embedding material 100 is subjected to a wire drawing process and then subjected to a heat treatment, as shown in FIG. 2, a first element wire group in which the plurality of element wires 201 are arranged on a concentric circle concentric with the central member 107 is formed around the central member 107. In addition, a second element wire group in which the plurality of element wires 201 are arranged on a concentric circle concentric with the central member 107 is formed outside the first element wire group.

According to the multi-core wire structure having such a multilayer structure, it is possible to increase the current density of the transport current per wire while reducing the AC loss and stabilizing superconduction. In the case of a multi-core wire structure having a multilayer structure, there is a possibility that uneven unevenness of the element wires 201 occurs in a cross section of the wire as viewed in the axial direction due to the wire drawing process. However, such unevenness can be prevented by providing the central member 107 and the high hardness metal 206. Therefore, for the MgB₂ superconducting wire 200, a multi-core wire structure having a multilayer structure can be adopted.

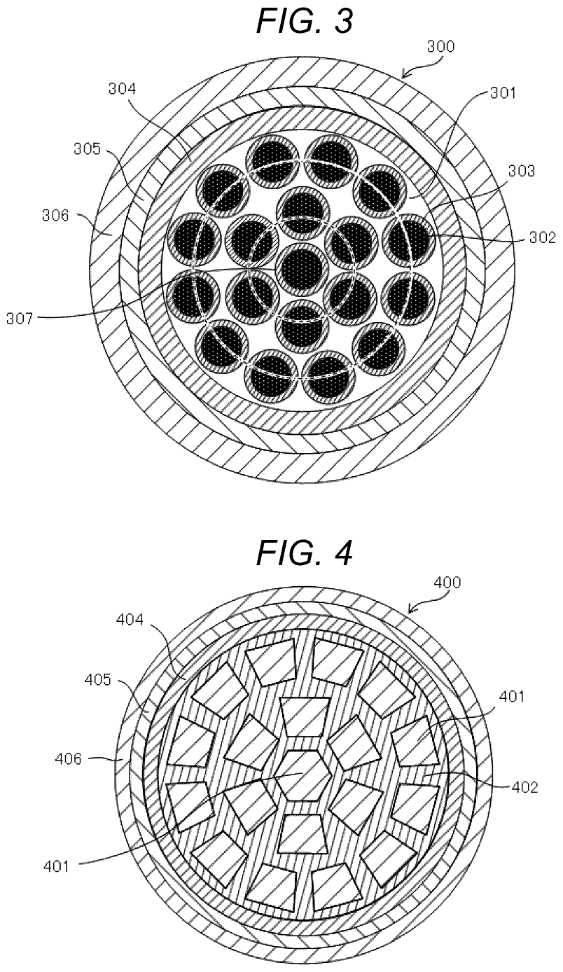

FIG. 3 is a sectional view schematically showing an example of an embedded material which is a material for an MgB₂ superconducting wire according to the embodiment of the present invention.

As shown in FIG. 3, the MgB₂ superconducting wire according to the present embodiment can also be provided in a structure in which an element wire precursor which is a precursor of a superconducting filament is disposed at the center. The embedding material 300 illustrated in FIG. 3 is formed by assembling a plurality of element wire precursors 301 in a metal multi-tube (304, 305, 306) in a regular arrangement, similarly to the embedding material 100 described above. The element wire precursor 301 is formed by filling the metal tube 303 with the raw material powder 302.

The embedding material 300 shown in FIG. 3 is different from the embedding material 100 in that the element wire precursor 301 which is a precursor of a superconducting filament is provided as a central member 307 instead of a metal (107) formed of a metal of a normal conductor. Other main configurations of the embedding material 300 are similar to those of the embedding material 100 described above.

FIG. 4 is a sectional view schematically showing an example of an MgB₂ superconducting wire according to the embodiment of the present invention.

As illustrated in FIG. 4, an MgB₂ superconducting wire 400 according to the present embodiment includes a plurality of element wires 401 which are superconducting filaments, a matrix (base material) 402 in which an element wire group is embedded, and metal layers 404, 405, and 406 having a multilayer structure.

The MgB₂ superconducting wire 400 illustrated in FIG. 4 is manufactured by performing a heat treatment after drawing the embedding material 300 illustrated in FIG. 3. The method for manufacturing the MgB₂ superconducting wire 400 according to the present embodiment includes the steps of: forming the embedding material 300 which is a precursor of the MgB₂ superconducting wire; drawing the embedding material 300; and heat-treating the embedding material 300 subjected to the drawing process to generate MgB₂.

The MgB₂ superconducting wire 400 according to the present embodiment is a superconducting wire having the plurality of element wires 401 containing MgB₂ and covered with metal layers (404, 405, and 406) having a multilayer structure. The MgB₂ superconducting wire 400 has a multi-core wire structure including the plurality of element wires 401 which are superconducting filaments. The plurality of element wires 401 are arranged in the circumferential direction and the radial direction with respect to the center of the wire to form an element wire group. In the matrix 402, the element wire group is buried inside the metal layers (404, 405, and 406).

The metal layers (404, 405, and 406) are provided in a multilayer structure in which the high thermal expansion metal 404, the stabilizer 405, and the high hardness metal 406 are arranged in this order from the inside to the outside. The high thermal expansion metal 404 is formed of the high thermal expansion metal tube 304. The stabilizer 405 is formed of the stabilizer tube 305. The high hardness metal 406 is formed of the high hardness metal tube 306.

Referring to FIG. 3, the embedding material 300 is provided in a structure in which a plurality of element wire precursors 301 are arranged in the circumferential direction and the radial direction with respect to the center of the embedding material 300. The central member 307 is disposed at the center of the embedding material 300. As the central member 307, an element wire precursor which is a precursor of a superconducting filament is disposed.

When the above embedding material 300 is subjected to a wire drawing process and then subjected to a heat treatment, as shown in FIG. 4, the element wire 401 which is a superconducting filament is formed at the center of the MgB₂ superconducting wire 400. In addition, an element wire group in which the plurality of element wires 401 are arranged in the circumferential direction and the radial direction with respect to the center of the wire is formed.

As shown in FIG. 3, when the central member 307, which is a precursor of the superconducting filament, is disposed at the center of the embedding material 300, the area of the superconducting filament increases in a cross section of the wire as viewed in the axial direction while the arrangement of the precursor group including the plurality of element wire precursors 301 is maintained. This makes it possible to increase the current density of the transport current per wire.

In the MgB₂ superconducting wire 200 or 400 according to the present embodiment, the number of layers of the element wires 201 or 401 and the number of element wires 201 or 401 per layer are not particularly limited. The number of layers of the element wires 201 or 401 and the number of element wires 201 or 401 per layer can be set to an appropriate number of 2 or more.

As shown in FIGS. 1 and 3, a multi-tube (104, 105, 106, 304, 305, 306) is formed by arranging a high thermal expansion metal tube (104, 304) made of a high thermal expansion metal (204, 404), a stabilizer tube (105, 305) made of a stabilizer (205, 405), and a high hardness metal tube (106, 306) made of a high hardness metal (206, 406) in this order from the inside to the outside.

A high thermal expansion metal (204, 404) is provided so as to cover the element wire group constituted by element wires (201, 401) and the outer periphery of a matrix (202, 402) over the length direction of the wire. A high thermal expansion metal is formed of a metal having a thermal expansion coefficient at room temperature higher than that of an element wire or a matrix, that is, MgB₂ or a material of a metal tube as a barrier material. The high thermal expansion coefficient is preferably secured even in a temperature range from the temperature of the heat treatment for producing MgB₂ to room temperature or a cryogenic temperature range equal to or lower than the critical temperature of MgB₂.

In general, it is considered that when a tensile load is applied to a superconducting wire and a critical tensile strain is exceeded, a crack or the like occurs in a superconducting filament, and superconducting properties deteriorate. When the superconducting wire is bent at the time of winding, routing, or the like into a coil shape, tensile strain is generated outside the bending, and compressive strain is generated inside the bending. When the tensile strain exceeds the residual compressive strain generated at the time of heat treatment, cracks and the like are generated in the superconducting filament.

On the other hand, when a high thermal expansion metal is provided, a compressive force due to a thermal expansion difference is applied to the element wire group after the heat treatment for generating MgB₂, and residual compressive strain can be applied to the superconducting filament. Since the limit tensile strain of the element wire is enlarged by an increase in residual compressive strain, the allowable bending radius of the wire can be made smaller than the related art.

The thermal expansion coefficient of the high thermal expansion metal at room temperature is preferably 14.0×10⁻⁶° C.⁻¹ or more, more preferably 14.5×10⁻⁶° C.⁻¹ or more, and still more preferably 15.0×10⁻⁶° C.⁻¹ or more. With such a high thermal expansion coefficient, a sufficiently high residual compressive strain can be applied to the element wire and the matrix.

Examples of the high thermal expansion metal include stainless steel, carbon steel, nickel steel, and nickel chromium steel. As the high thermal expansion metal, stainless steel or carbon steel is preferable. Stainless steel and carbon steel are inexpensive and are excellent in availability, so that the material cost of the wire can be suppressed. As stainless steel and carbon steel, appropriate types can be used as long as the thermal expansion coefficient at room temperature is higher than that of MgB₂ and the material of the metal tube as a barrier material, and appropriate workability is secured.

The high thermal expansion metal is more preferably low-carbon stainless steel having a C content of 0.03 mass % or less or low-carbon steel having a C content of 0.01 mass % or more and less than 0.25 mass %. Specific examples of the low-carbon stainless steel include SUS301L, SUS304L, and SUS316L. The high thermal expansion metal is preferably a material in which the content of nickel that hinders the production of MgB₂ is 10 mass % or less.

Low carbon stainless steel and low carbon steel are materials each having a relatively high hardness among stainless steel and carbon steel having high thermal expansion coefficients and certain degrees of ductility. Therefore, when a stabilizer is sandwiched between the low-carbon stainless steel or the low-carbon steel and the high-hardness metal, the high thermal expansion metal and the stabilizer can be brought into close contact with each other with high uniformity by the processing force applied from the outside at the time of wire drawing. When the high thermal expansion metal and the stabilizer are brought into close contact with each other, a difference in deformation amount between the high thermal expansion metal and the stabilizer is suppressed at the time of wire drawing. Therefore, it is possible to lengthen or thin the wire as compared with cases using materials other than low carbon stainless steel or low carbon steel. In addition, this prevents the element wire group from being biased in the radial direction.

The stabilizer (205, 405) is provided so as to cover the outer periphery of the high thermal expansion metal (204, 404) over the length direction of the wire. The stabilizer is formed of a good conductor having a low resistivity and a high thermal conductivity. When the stabilizer is provided, superconduction can be thermally and magnetically stabilized, and quenching and thermal runaway of the wire can be suppressed.

As the stabilizer, copper is preferable. Examples of the copper include phosphorus-deoxidized copper, tough pitch copper, and oxygen-free copper. The copper is particularly preferably oxygen-free copper. In the case of oxygen-free copper, high conductivity and thermal conductivity can be obtained, and thus thermal stability and magnetic stability of superconduction can be further improved.

The high hardness metal (206, 406) is provided so as to cover the outer periphery of the stabilizer (205, 405) over the length direction of the wire. The high hardness metal is formed of a metal having a higher hardness than the stabilizer. The hardness is preferably secured at least in a temperature range from the temperature of the heat treatment for producing MgB₂ to room temperature. The hardness of the high hardness metal can be evaluated by, for example, Vickers hardness (HV).

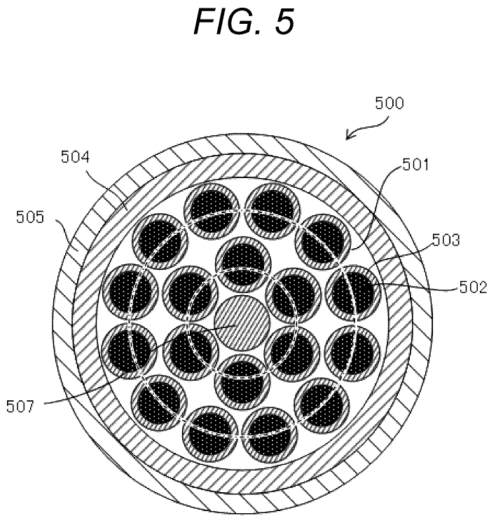

FIG. 5 is a sectional view schematically showing an example of an embedded material which is a precursor of a conventional MgB₂ superconducting wire.

As illustrated in FIG. 5, a conventional MgB₂ superconducting wire is manufactured using an embedding material 500 having a multi-core wire structure as a precursor. The embedding material 500 is formed by assembling a plurality of element wire precursors 501, which are precursors of superconducting filaments, in a metal multi-tube (504, 505). The element wire precursor 501 is formed by filling the metal tube 503 with the raw material powder 502.

In the conventional embedding material 500, the multi-tube (504, 505) is formed by arranging the high thermal expansion metal tube 504 formed of a high thermal expansion metal and the stabilizer tube 505 formed of a stabilizer in this order from the inside to the outside. A metal tube having high hardness is not disposed outside the stabilizer tube 505, and the stabilizer forms an outermost layer.

As in the related art, when the outermost layer of the embedding material is a stabilizer, the stabilizer of the outermost layer receives a direct processing force from the outside at the time of wire drawing. The stabilizer such as copper is a material that is easily deformed and has excellent workability. On the other hand, a high thermal expansion metal such as stainless steel is hardly deformed and is poor in workability. Therefore, when the outermost layer of the embedding material is the stabilizer, the high thermal expansion metal is not greatly deformed, but the stabilizer is greatly deformed.

As a result, a difference in deformation amount is likely to occur between the inner high thermal expansion metal and the outer stabilizer. Only the stabilizer is greatly reduced in surface area and greatly extends in the drawing direction. On the other hand, the high thermal expansion metal and the element wire group inside the high thermal expansion metal are not sufficiently reduced in surface area and do not extend in the wire drawing direction. Since the area reduction ratio and the wire length are capped at the time of wire drawing of the embedding material, there is a problem that wire formation of the embedding material is hindered.

In particular, when a machining force is non-uniformly applied to the stabilizer from the outside, only a part of the stabilizer in the circumferential direction may be locally thinned. In a cross section of the wire as viewed in the axial direction, irregularities may be generated at the interface between the high thermal expansion metal and the stabilizer. When such a difference in deformation amount occurs, there is a problem that the element wire precursors are biased in the radial direction at the time of wire drawing.

When the biased element wire precursors are fired, the element wires are also biased in the radial direction. When such element wires are formed, the curvatures of some element wires increase when the wire is bent. Since an excessive tensile load is likely to be applied to some element wires, cracks and the like are generated, and the superconducting properties deteriorate.

In contrast to this, when a high hardness metal (206, 406) is provided on the outer side of a stabilizer (205, 405), it is possible to suppress a deformation amount difference generated between the high thermal expansion metal and the stabilizer at the time of wire drawing. Since the high hardness metal is present on the outer side of the stabilizer, the processing force applied from the outer side can be uniformly applied to the element wire precursor, the high thermal expansion metal, and the stabilizer in the circumferential direction via the high hardness metal.

Therefore, when the high hardness metal (206, 406) is provided outside the stabilizer (205, 405), the high thermal expansion metal and the stabilizer can be reduced in area in a well-balanced manner and can be stretched in the drawing direction. As compared with the related art, it is possible to further lengthen the wire and further thin the wire within a range in which the arrangement of the element wires and the superconducting properties are secured. Further, it is possible to prevent the occurrence of biasing in the radial direction in the arrangement of the element wire precursors at the time of wire drawing. Even if a multi-core wire structure having a multilayer structure is adopted, the allowable bending radius of the wire can be made smaller than that in the related art.

As the high hardness metal, a metal having a higher thermal expansion coefficient at room temperature than an element wire or a matrix, that is, MgB₂ or a material for a metal tube as a barrier material is preferable. In addition, a metal having a higher thermal expansion coefficient at room temperature than the stabilizer is preferable. When the metal has a high thermal expansion coefficient, a compressive force due to a thermal expansion difference can be applied to the superconducting filament after the heat treatment for generating MgB₂.

As the high hardness metal, a copper alloy or an alloy containing copper is preferable. When the wire is a copper alloy or an alloy containing copper, a high hardness metal can be easily removed at the time of superconducting connection of the wire. When a wire is superconducting-connected, it is necessary to expose an element wire which is a superconducting filament. However, when the high hardness metal is a copper alloy or an alloy containing copper, the high hardness metal can be easily removed by being dissolved with nitric acid or the like.

As the high hardness metal, a Ni—Cu alloy, a Cu—Ni alloy, or dispersion-strengthened copper is more preferable, and a Ni—Cu alloy or a Cu—Ni alloy is particularly preferable. When these copper alloys are used, an appropriate high hardness can be obtained within a processable range. In addition, an alloy containing Ni is preferable as the outermost layer of the wire because nonmagnetism and corrosion resistance are obtained.

The Cu—Ni alloy is not particularly limited, and examples thereof include white copper having Ni content of 10 mass % or more and 30 mass % or less. The Ni—Cu alloy is not particularly limited, and examples thereof include Monel having a Cu content of 20 mass % or more and 35 mass % or less. Examples of the dispersion-strengthened copper include alumina dispersion-strengthened copper in which alumina is dispersed, zirconia dispersion-strengthened copper in which zirconia is dispersed, and yttria dispersion-strengthened copper in which yttria is dispersed.

After wire drawing, it is preferable that the high thermal expansion metal, the stabilizer, and the high-hardness metal are in close contact with each other to form an integrated metal layer. Such a metal layer can be formed by arranging the high thermal expansion metal tube (104, 304), the stabilizer tube (105, 305), and the high hardness metal tube (106, 306) with small gaps therebetween at the time of forming the embedding material (100, 300).

When such an integrated metal layer is formed, the high thermal expansion metal and the stabilizer can be brought into close contact with each other with high uniformity in the circumferential direction by the processing force applied from the outside at the time of wire drawing. Since only the stabilizer is prevented from being greatly deformed, a deformation amount difference between the high thermal expansion metal and the stabilizer can be sufficiently suppressed. When such an integrated metal layer is formed, it is preferable that a layer exhibiting other functions is not provided between the high thermal expansion metal and the stabilizer or between the stabilizer and the high hardness metal.

Referring to FIGS. 1, 2, 3, and 4, the MgB₂ superconducting wire 200 or 400 and the embedding material 100 or 300 are provided as round wires. However, the MgB₂ superconducting wire 200 or 400 and the embedding material 100 or 300 can be provided in a polygonal shape such a rectangle or a hexagon, or in an appropriate cross-sectional shape such as a rectangular wire. The number of layers of the element wires 201 or 401 and the number of element wires 201 or 401 per layer can be set to an appropriate number of 2 or more.

Next, a method for manufacturing the superconducting wire will be described. In the following description, a method for manufacturing the MgB₂ superconducting wire 200 illustrated in FIG. 2 by an in situ method using the embedding material 100 illustrated in FIG. 1 will be exemplified.

The MgB₂ superconducting wire according to the present embodiment includes a preparation step of forming an embedding material, a drawing processing step of drawing the embedding material, and a heat treatment step of heat-treating the embedding material subjected to the drawing processing to generate MgB₂. In the preparation step, a plurality of single core wires to be embedded are prepared as element wire precursors for forming a multi-core wire structure. The single core wires to be embedded are embedded into a multi-tube composed of a high thermal expansion metal tube, a stabilizer tube, and a high hardness metal tube.

In the preparation step, a raw material powder is prepared by mixing a magnesium powder and a boron powder, and a metal tube formed of a barrier material is filled with the raw material powder. The raw material powder is prepared by weighing a magnesium powder and a boron powder as raw materials for MgB₂ so that the molar ratio of Mg and B is about 1:2, and pulverizing and mixing the magnesium powder and the boron powder. A carbon source for element substitution can be added to the raw material powder as necessary.

The raw material powder is preferably handled in an inert gas atmosphere such as nitrogen or argon, or a non-oxidizing atmosphere such as a vacuum atmosphere. The amount of oxygen and the amount of moisture in the atmosphere are preferably 10 ppm or less. Raw material powder mixing can be performed by a ball mill apparatus, a planetary mixer, a V-type mixer, a mortar, or the like.

In addition, raw material powder mixing can be performed by a mechanical milling method. In the mechanical milling method, particles of a raw material powder are caused to intensely collide with a medium such as zirconia balls or the inner wall of a pot, and pulverization and mixing are performed while being strongly processed. In the mechanical milling, it is preferable to apply collision energy to such an extent that MgB₂ is not clearly generated. The production of MgB₂ can be confirmed by the substantial presence or absence of a peak of MgB₂ in powder X-ray diffraction.

According to the mechanical milling method, the B particles enter the Mg particles, and a powder structure in which B is finely dispersed and contained in the matrix of Mg and having a high mixing degree is obtained. Therefore, when such a powder structure is heat-treated, a superconducting filament having many bonds between MgB₂ and few voids can be formed. When a superconducting filament having a small number of voids is formed, a high critical current density is obtained.

Subsequently, the metal tube filled with the raw material powder is subjected to a wire drawing process to produce a single core wire to be embedded. As the single core wire to be embedded, a plurality of wires constituting an element wire group having a multi-core wire structure are prepared. It is preferable that the plurality of single core wires to be embedded are manufactured with the same wire diameter. The drawing process of the single core wire to be embedded can be performed with an appropriate number of passes. The drawing process of the single core wire to be embedded is preferably performed with an area reduction ratio of 8% to 12% per pass.

The drawing process of the single core wire to be embedded can be performed by a wire drawing process, an extrusion process, a swaging process, a cassette roll process, a groove roll process, and the like. As a wire drawing device, a drawbench, a hydrostatic extruder, a wire drawing machine, a swager, a cassette roller die, a groove roll, or the like can be used.

Subsequently, a plurality of single core wires to be embedded subjected to a wire drawing process are embedded into a multi-tube having a multilayer structure together with a central member to prepare an embedding material which is a precursor of an MgB₂ superconducting wire. The multi-tube is formed by arranging a high thermal expansion metal tube formed of a high thermal expansion metal, a stabilizer tube formed of a stabilizer, and a high hardness metal tube formed of a high hardness metal in this order from the inside to the outside.

When single core wires to be embedded are embedded into the multi-tube, it is preferable to arrange the plurality of single core wires to be embedded around the central member so as to be concentric with the central member. It is preferable that the respective single core wires to be embedded are regularly arranged at equal intervals so as to be line-symmetric with respect to a center line passing through the central member. In addition, it is preferable that the central member and the single core wires to be embedded, the single core wires to be embedded, and the single core wires to be embedded and the high thermal expansion metal tube are disposed in contact with each other.

With such an arrangement, it is possible to apply a processing force with high uniformity in the circumferential direction from the high hardness metal tube to the inner stabilizer tube and the like at the time of wire drawing. In addition, after the heat treatment for generating MgB₂, a compressive force due to the thermal expansion difference can be uniformly applied to the element wire group from the high thermal expansion metal. Since the biasing of the arrangement of the element wire precursors in the radial direction is suppressed at the time of wire drawing, it is possible to reduce an excessive load and a magnetic loss at the time of wire bending.

In the wire drawing process, a wire drawing process is performed on an embedding material in which a plurality of single core wires to be embedded are embedded into a multi-tube. The embedding material is elongated and thinned by performing a wire drawing process on the embedding material at a predetermined area reduction ratio. The drawing process of the embedding material can be performed with an appropriate number of passes. The wire drawing process of the embedding material 100 can be performed such that the wire diameter is, for example, 0.3 mm to 2.0 mm. In addition, the wire diameter can be set to a wire diameter according to the application.

The drawing process of the embedding material can be performed by a wire drawing process, an extrusion process, a swaging process, a cassette roll process, a groove roll process, or the like. As a wire drawing device, a drawbench, a hydrostatic extruder, a wire drawing machine, a swager, a cassette roller die, a groove roll, or the like can be used.

In addition, the embedding material subjected to the drawing process can be twisted in a spiral shape. When the single core wire to be embedded is spirally twisted, a coupling current between the superconducting filaments can be reduced. The twist pitch can be, for example, 10 mm to 100 mm.

In the heat treatment process, the embedding material subjected to the wire drawing process is subjected to a heat treatment to produce MgB₂. When the embedding material is heat-treated at a predetermined temperature or higher, Mg and B in the raw material powder filled in the single core wire to be embedded react with each other, and an element wire (MgB₂ filament) containing MgB₂ is formed. When the obtained MgB₂ superconducting wire is cooled to room temperature or the critical temperature or lower after heat treatment, a compressive force due to a thermal expansion difference is applied to the element wire group from the high thermal expansion metal, and residual compressive strain is applied to the MgB₂ filament.

The heat treatment atmosphere is preferably an inert gas atmosphere such as nitrogen or argon, or a non-oxidizing atmosphere such as a vacuum atmosphere. The amount of oxygen and the amount of moisture in the atmosphere are preferably 10 ppm or less. A heat treatment may be performed after winding the embedding material subjected to the wire drawing process into a coil shape or the like, or may be performed before winding the embedding material subjected to the wire drawing process into a coil shape or the like. For example, when a heat-resistant insulating material such as glass fiber is used, an insulating coating can be applied before heat treatment.

The heat treatment temperature is, for example, 550° C. to 800° C., preferably 560° C. to 700° C., and more preferably 580° C. to 620° C. As the heat treatment temperature is higher at 550° C. or higher, the reaction for producing MgB₂ easily proceeds due to the diffusion of Mg. In addition, since the thermal expansion of the high thermal expansion metal increases, a large residual compression strain can be imparted. On the other hand, as the heat treatment temperature is lower at 800° C. or lower, the grain growth of MgB₂ is suppressed, so that the density of grain boundaries serving as pinning centers increases, and a high critical current density is obtained.

The heat treatment time is, for example, several ten minutes to several ten hours, preferably 2 hours to 16 hours, and more preferably 3 hours to 12 hours. When the heat treatment time is 3 hours or more, MgB₂ can be usually sufficiently generated. In addition, when the heat treatment time is 12 hours or less, the grain growth of MgB₂ is suppressed, the density of grain boundaries serving as pinning centers increases, and a high critical current density is obtained.

According to the MgB₂ superconducting wire and the method for manufacturing an MgB₂ superconducting wire according to the present embodiment described above, since a high hardness metal is provided on the outside of the stabilizer, it is possible to apply a processing force to the inside through the high hardness metal which is hardly deformed at the time of wire drawing. Therefore, the high thermal expansion metal and the stabilizer can be brought into close contact with each other with high uniformity in the circumferential direction. At the time of wire drawing, it is possible to prevent only the stabilizer from greatly decreasing in area or prevent only the stabilizer from greatly extending in the wire drawing direction, so that the difference in deformation amount between the high thermal expansion metal and the stabilizer is suppressed. Therefore, it is possible to perform a wire drawing process having a large area reduction ratio while ensuring the superconducting properties of the wire as compared with the related art, and it is possible to further lengthen and thin the wire.

In addition, since the non-uniform deformation of the stabilizer and the high thermal expansion metal is suppressed, the radial biasing of the element wire group is prevented. Even in a case where the multi-core wire structure having the multilayer structure is adopted, since the element wire group is arranged symmetrically with respect to the center of the wire, when the wire is bent, the occurrence of excessive tensile strain in only a part of the element wire group is prevented. Therefore, the allowable bending radius of the wire can be further reduced as compared with the related art. Since the bending strain resistance of the element wire group as a whole is improved, the superconducting properties of the wire can be stably maintained even when bending with a small radius is applied.

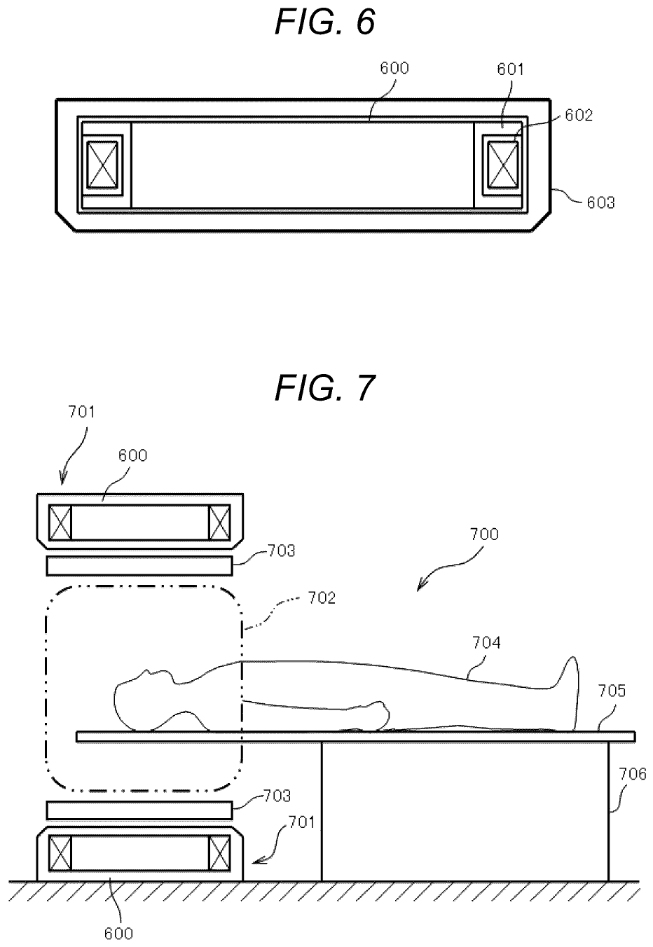

FIG. 6 is a sectional view schematically illustrating an example of a superconducting coil according to the embodiment of the present invention.

As shown in FIG. 6, the MgB₂ superconducting wire containing a high hardness metal can be used as a superconducting coil 600 wound in a coil shape. The superconducting coil 600 according to the present embodiment includes a bobbin 601, an MgB₂ superconducting wire 602 wound in a coil shape, and a cooling container 603.

As a method for preparing the superconducting coil 600, either a wind-and-react method or a react-and-wind method may be used. When the react-and-wind method is used, distortion is likely to occur in the element wire at the time of winding after heat treatment. However, since the MgB₂ superconducting wire including a high hardness metal has a small allowable bending radius, it is possible to obtain appropriate superconducting properties even when the MgB₂ superconducting wire experiences distortion due to bending, as compared with the related art.

The bobbin 601 can be formed of, for example, a metal having high thermal conductivity. The bobbin 601 is preferably made of copper, and particularly preferably made of oxygen-free copper. When the thermal conductivity of the bobbin 601 is high, the MgB₂ superconducting wire 602 can be cooled with high uniformity. The bobbin 601 is covered with an insulating material (not illustrated). As the insulating material, it is preferable to use a heat-resistant material that withstands heat treatment when a wind-and-react method is used. Examples of the heat-resistant insulating material include glass braiding formed of glass fiber.

The MgB₂ superconducting wire 602 can be wound around the bobbin 601. When the wind-and-react method is used, the MgB₂ superconducting wire 602 may be electrically insulated by a heat-resistant insulating material before heat treatment for generating MgB₂. After the heat treatment for generating MgB₂, the MgB₂ superconducting wire 602 may be electrically insulated by being impregnated with an insulating resin. In contrast to this, when the react-and-wind method is used, after heat treatment for generating MgB₂ and winding the MgB₂ into a coil shape, the MgB₂ superconducting wire 602 may be impregnated with an insulating resin to be electrically insulated.

The cooling container 603 is a container having a sealed structure and accommodates the MgB₂ superconducting wire 602 wound around the bobbin 601 in a coil shape. The cooling container 603 is provided in a structure with inside and outside surfaces being insulated by vacuum insulation, a heat insulating material, a heat shield, or the like. The cooling container 603 may be filled with a cooling medium or may be conductively cooled by a refrigerator.

According to such a superconducting coil, since the MgB₂ superconducting wire having the high hardness metal provided outside the stabilizer is provided, the allowable bending radius of the wire is further reduced as compared with the related art. Since bending having a small radius is allowed, it is possible to adopt a superconducting coil having a small coil diameter or a structure having a superconducting coil whose outlet has a small bending radius. Therefore, a superconducting coil suitable for miniaturization and space saving can be obtained.

FIG. 7 is a sectional view schematically illustrating an example of a magnetic generator according to the embodiment of the present invention. FIG. 7 illustrates a magnetic resonance imaging (MRI) apparatus as an example of the magnetic generator.

As illustrated in FIG. 7, the MgB₂ superconducting wire including a high hardness metal can be provided as the superconducting coil 600 in an MRI apparatus (magnetic generator) 700. The MRI apparatus 700 according to the present embodiment includes a static magnetic field generating unit 701 configured by the superconducting coil 600 of the above MgB₂ superconducting wire wound in a coil shape.

The MRI apparatus 700 includes a pair of static magnetic field generating units 701, an imaging region 702, and gradient magnetic field generating units 703. Referring to FIG. 7, the static magnetic field generating units 701 are coupled to each other via a coupling member (not illustrated), and the static magnetic field generating units 701 are arranged vertically so as to face each other across the imaging region 702. The gradient magnetic field generating units 703 are disposed between the static magnetic field generating units 701 and the imaging region 702.

The MRI apparatus 700 includes a bed 705 on which a subject 704 is place and a conveyance mechanism 706 that conveys the bed 705. The bed 705 is provided to be movable back and forth with respect to the imaging region 702. When the bed 705 is conveyed by the conveyance mechanism 706, the subject 704 placed on the bed 705 can move forward and backward with respect to the imaging region 702.

The static magnetic field generating unit 701 includes the superconducting coil 600 described above. The static magnetic field generating unit 701 includes a coil unit and a permanent current switch. The coil part and the permanent current switch can be formed of the MgB₂ superconducting wire. The circuit of the static magnetic field generating unit 701 is electrically connected to a power supply (not illustrated) via a normal conductor.

An excitation current flows in the coil unit of the static magnetic field generating unit 701 in a state where the permanent current switch is turned off. When the permanent current switch is switched to the ON state, a permanent current flows. The permanent current flowing through the coil unit generates a static magnetic field having high temporal stability in the imaging region 702. The higher the strength of the static magnetic field, the higher the nuclear magnetic resonance frequency, and thus the frequency resolution can be improved.

The gradient magnetic field generating unit 703 is supplied with a time-varying current and generates a gradient magnetic field having a spatial distribution in the imaging region 702. When an oscillating magnetic field having a nuclear magnetic resonance frequency is applied to the imaging region 702, a resonance signal is generated from the subject 704 and received by a reception coil (not illustrated). The received resonance signal is imaged as a magnetic resonance tomographic image of the subject 704 by Fourier transform. The subject 704 can be inspected and diagnosed by imaging in the form of a two-dimensional contrast image or the like.

According to such an MRI apparatus, since a superconducting coil obtained by winding an MgB₂ superconducting wire provided with a high hardness metal on the outside of a stabilizer is provided, the allowable bending radius of the wire is further reduced as compared with the related art, and it is possible to reduce the size of the magnetic field generating unit and achieve space saving. In addition, since it is possible to adopt a structure in which the outlet of the superconducting coil has a small bending radius, multiplexing of the superconducting coil is facilitated.

Although an embodiment of the present invention has been described above, the present invention is not limited to the above-described embodiment, and various modifications can be made without departing from the gist of the present invention. For example, the present invention is not necessarily limited to those having all the configurations included in the above-described embodiment. A part of the configuration of a given embodiment can be replaced with another configuration, a part of the configuration of a given embodiment can be added to another embodiment, or a part of the configuration of a given embodiment can be omitted.

For example, the superconducting coil is provided in an MRI apparatus, but the MgB₂ superconducting wire including a high hardness metal may be provided as a superconducting coil in another magnetic generator such as a nuclear magnetic resonance (NMR) apparatus. In other magnetic generators, downsizing and space saving can be achieved. In addition, since the bending radius of the outlet of the superconducting coil can be reduced, multiplexing of the superconducting coil is facilitated.

### EXAMPLES

Hereinafter, the present invention will be specifically described with reference to examples, but the technical scope of the present invention is not limited thereto.

### Example 1

An MgB₂ superconducting wire having a multi-core wire structure shown in FIG. 1 was prepared.

First, a single core wire to be embedded as a precursor of a superconducting filament was prepared by the following procedure. A magnesium powder and a boron powder as raw materials were weighed so that the molar ratio between Mg and B was about 1:2, and pulverized and mixed using a ball mill to prepare a raw material powder. Then, the obtained raw material powder was filled in an Fe tube.

Subsequently, the Fe tube filled with the mixed powder was subjected to a wire drawing process to obtain a single core wire to be embedded. The wire drawing process of the Fe pipe was performed by a wire drawing process using a wire drawing die. The area reduction ratio per pass was set to 8% to 128, and a pass was repeated a plurality of times. In addition, a central member made of the same material as that of the Fe tube filled with the raw material powder was prepared by swaging using a swager. The wire diameters of the single core wire to be embedded and the central member were the same.

Subsequently, 6 single core wires to be embedded were arranged so as to surround the periphery of the prepared central member, and 12 single core wires to be embedded were further arranged so as to cover the outer periphery thereof. Then, these single core wire groups to be embedded were inserted into a high thermal expansion metal tube, the high thermal expansion metal tube was inserted into a stabilizer tube, and the stabilizer tube was inserted into a high hardness metal tube to obtain an embedding material as a precursor of an MgB₂ superconducting wire.

An SUS316L tube was used as the high thermal expansion metal tube, an oxygen-free copper tube was used as the stabilizer tube, and a Monel tube was used as the high hardness metal tube.

Subsequently, the prepared embedding material was subjected to a wire drawing process to be thinned. The wire drawing process was performed by a wire drawing process using a wire drawing die. In the wire drawing process, thinning was performed by repeating a plurality of passes with an area reduction ratio per pass being set to 5% to 12%.

Subsequently, a cross section of the thinned embedding material in the radial direction was observed with a microscope. As a result, it was confirmed that the inner 6 single core wires to be embedded and the outer 12 single core wires to be embedded were regularly arranged in the radial direction as arranged at the time of insertion. In addition, a multilayer structure in which a high thermal expansion metal, a stabilizer, and a high hardness metal were disposed in this order from the inside to the outside was confirmed. The high thermal expansion metal and the stabilizer were reduced to a highly uniform thickness in the circumferential direction. It has been confirmed that deformation and arrangement disturbance at the time of wire drawing can be reduced by disposing a high hardness metal outside the stabilizer.

Subsequently, the thinned embedding material was heat-treated at a temperature of 600° C. to generate MgB₂ from the raw material powder, thereby producing an MgB₂ superconducting wire.

### Example 2

An MgB₂ superconducting wire having a multi-core wire structure shown in FIG. 3 was prepared.

First, a single core wire to be embedded as a precursor of a superconducting filament was prepared in the same procedure as in Example 1. The drawing process of the metal tube was performed by repeating a plurality of passes with an area reduction ratio per pass being set to 9% to 12%.

Subsequently, 6 single core wires to be embedded were arranged so as to surround the periphery of the one prepared single core wire, and 12 single core wires to be embedded were further arranged so as to cover the outer periphery thereof. Then, as Example 1, these single core wire groups to be embedded were inserted into a high thermal expansion metal tube, the high thermal expansion metal tube was inserted into a stabilizer tube, and the stabilizer tube was inserted into a high hardness metal tube to obtain an embedding material as a precursor of an MgB₂ superconducting wire.

Subsequently, the prepared embedding material was subjected to a wire drawing process to be thinned. The wire drawing process was performed by a wire drawing process using a wire drawing die. In the wire drawing process, thinning was performed by repeating a plurality of passes with an area reduction ratio per pass being set to 5% to 12%.

Subsequently, a cross section of the thinned embedding material in the radial direction was observed with a microscope. As a result, it was confirmed that the one central single core wire to be embedded, the inner 6 single core wires to be embedded and the outer 12 single core wires to be embedded were regularly arranged in the radial direction as arranged at the time of insertion. In addition, a multilayer structure in which a high thermal expansion metal, a stabilizer, and a high hardness metal were disposed in this order from the inside to the outside was confirmed. The high thermal expansion metal and the stabilizer were reduced to a highly uniform thickness in the circumferential direction. It has been confirmed that the deformation and arrangement disturbance of the element wires at the time of wire drawing can be reduced by disposing a high hardness metal outside the stabilizer.

Subsequently, the thinned embedding material was heat-treated at a temperature of 600° C. to generate MgB₂ from the raw material powder, thereby producing an MgB₂ superconducting wire.

### Comparative Example 1

An MgB₂ superconducting wire having a multi-core wire structure shown in FIG. 5 was prepared.

First, a single core wire to be embedded as a precursor of a superconducting filament was prepared in the same procedure as in Example 1. In addition, a central member made of the same material as the metal tube filled with the raw material powder was prepared in the same procedure as in Example 1. The drawing process of the metal tube was performed by repeating a plurality of passes with an area reduction ratio per pass being set to 9% to 12%.

Subsequently, in the same manner as in Example 1, 6 single core wires to be embedded were arranged so as to surround the periphery of the prepared central member, and 12 single core wires to be embedded were further arranged so as to cover the outer periphery thereof. Then, these single core wire groups to be embedded were inserted into a high thermal expansion metal tube, and the high thermal expansion metal tube was inserted into a stabilizer tube to obtain an embedding material as a precursor of an MgB₂ superconducting wire.

An SUS316L tube was used as the high thermal expansion metal tube, an oxygen-free copper tube was used as the stabilizer tube.

Subsequently, the prepared embedding material was subjected to a wire drawing process to be thinned. The wire drawing process was performed by a wire drawing process using a wire drawing die. The drawing process was performed by repeating a plurality of passes with an area reduction ratio per pass being set to 8% to 12%.

Subsequently, a cross section of the thinned embedding material in the radial direction was observed with a microscope. As a result, a portion locally thinned was observed only in a part of the stabilizer in the circumferential direction. In addition, the thickness of the stabilizer was uneven, and irregularities were observed at the interface with the high thermal expansion metal. It has been confirmed that when the high hardness metal is not disposed on the outside of the stabilizer, the wire drawing process leads to the deformation of the element wire and disturbance of the arrangement.

As a result of comparison between Examples 1 and 2 and Comparative Example 1, it was found that when the high hardness metal is not disposed outside the stabilizer, there is a limit to the elongation and thinning of the wire. It has been confirmed that when a high hardness metal is disposed outside the stabilizer, the wire can be made longer and thinner than before.

### Example 3

A superconducting coil was produced using the MgB₂ superconducting wire having the multi-core wire structure illustrated in FIG. 1.

First, an embedding material was prepared in the same procedure as in Example 1, and the embedding material was subjected to a wire drawing process. Then, the embedding material thinned by a wire drawing process was covered with an insulating material made of glass fiber. A metal bobbin was covered with a glass fiber insulating material. Then, the thinned embedding material was wound around a bobbin and heat-treated at a temperature of 600° C. to produce MgB₂. Thereafter, the MgB₂ superconducting wire was impregnated with an insulating resin and fixed to produce a superconducting coil.

Subsequently, the obtained superconducting coil was housed in a refrigeration container, and the superconducting coil was electrically connected to a power supply. Then, the superconducting coil was excited to confirm magnetic field stability.

### Example 4

An MRI apparatus including the superconducting coil using the MgB₂ superconducting wire having the multi-core wire structure illustrated in FIG. 1 was produced.

The MRI apparatus includes a pair of static magnetic field generating units and a gradient magnetic field generating unit. The static magnetic field generating units were coupled to each other via a coupling member (not illustrated). The static magnetic field generating units were arranged vertically so as to face each other. The gradient magnetic field generating unit was disposed between the static magnetic field generating units so as to sandwich the imaging region. In addition, a bed and a conveyance mechanism that conveys the bed are provided so as to be movable forward and backward with respect to the imaging region.

Subsequently, the obtained superconducting coil was housed in a refrigeration container and disposed in a static magnetic field generating unit. Then, the superconducting coil was electrically connected to a power supply. It has been confirmed that the superconducting coil using the produced MgB₂ superconducting wire normally operates in an MRI apparatus.

### REFERENCE SIGNS LIST

100, 300, 500 embedding material
101, 301, 501 element wire precursor
102, 302, 502 raw material powder
103, 303, 503 metal tube
104, 304, 504 high thermal expansion metal tube
105, 305, 505 stabilizer tube
106, 306 high hardness metal tube
107, 307, 507 central member
200, 400 MgB₂ superconducting wire
201, 401 element wire
202, 402 matrix (base material)
204, 404 high thermal expansion metal
205, 405 stabilizer
206, 406 high hardness metal
600 superconducting coil
601 bobbin
602 MgB₂ superconducting wire
603 cooling container
700 MRI apparatus (magnetic generator)
701 static magnetic field generating unit
702 imaging region
703 gradient magnetic field generating unit
704 subject
705 bed
706 conveyance mechanism

1. An MgB₂ superconducting wire having a plurality of element wires containing MgB₂ and covered with a metal layer, the MgB₂ superconducting wire comprising:
an element wire group having the plurality of element wires arranged in a circumferential direction and a radial direction with respect to a center of a wire;
a high thermal expansion metal that is disposed so as to cover the element wire group and has a higher thermal expansion coefficient at room temperature than that of the element wire;
a stabilizer that is disposed so as to cover the high thermal expansion metal and stabilizes superconduction; and
a high hardness metal that is disposed so as to cover the stabilizer and has a higher hardness than that of the stabilizer.

2. The MgB₂ superconducting wire according to claim 1, further comprising a base material in which the element wire group is embedded,
wherein the high thermal expansion metal is a metal having a higher thermal expansion coefficient at room temperature than those of the element wire and the base material.

3. The MgB₂ superconducting wire according to claim 1, wherein the high thermal expansion metal, the stabilizer, and the high hardness metal are in close contact with each other to form the integrated metal layer.

4. The MgB₂ superconducting wire according to claim 1, wherein the high thermal expansion metal is low carbon stainless steel or low carbon steel.

5. The MgB₂ superconducting wire according to claim 1, wherein the stabilizer is an MgB₂ superconducting wire made of copper.

6. The MgB₂ superconducting wire according to claim 1, wherein the high hardness metal is a Ni—Cu alloy or a Cu—Ni alloy.

7. The MgB₂ superconducting wire according to claim 1, further comprising a base material in which the element wire group is embedded,
wherein the base material is iron or niobium.

8. The MgB₂ superconducting wire according to claim 1, further comprising:
a central member disposed at a center of the wire; and
a base material in which the element wire group and the central member are embedded,
wherein the central member is formed of the same metal as the base material.

9. The MgB₂ superconducting wire according to claim 1, further comprising a central member disposed at a center of a wire,
wherein the central member is an element wire containing MgB₂.

10. A method for manufacturing an MgB₂ superconducting wire having a plurality of element wires containing MgB₂ and covered with a metal layer, the method comprising:
a step of forming an embedding material having precursors of the plurality of element wires accommodated in a multi-tube;
a step of performing a wire drawing process on the embedding material; and
a step of heat-treating the embedding material subjected to the wire drawing process to produce MgB₂,
wherein the embedding material has the precursors of the plurality of element wires accommodated in the multi-tube and arranged in a circumferential direction and a radial direction with respect to a center of the multi-tube, and
the multi-tube includes a high thermal expansion metal tube formed of a high thermal expansion metal having a higher thermal expansion coefficient at room temperature than that of the element wire, a stabilizer tube formed of a stabilizer for stabilizing superconduction, and a high hardness metal tube formed of a high hardness metal having a higher hardness than that of the stabilizer, which are arranged in this order from an inside to an outside.

11. The method for manufacturing an MgB₂ superconducting wire defined in claim 10, wherein
the embedding material has a central member disposed at a center of the multi-tube,
the precursor of the element wire accommodates a powder containing magnesium and boron in a metal tube, and
the central member is formed of the same metal as the metal tube.

12. The method for manufacturing an MgB₂ superconducting wire according to claim 10, wherein
the high thermal expansion metal is low carbon stainless steel or low carbon steel,
the stabilizer is copper, and
the high hardness metal is a Ni—Cu alloy or a Cu—Ni alloy.

13. A superconducting coil obtained by winding the superconducting wire defined in claim 1.

14. A magnetic generator comprising the superconducting coil obtained by winding the superconducting wire defined in claim 1.
